(19) United States
(12) Patent Application Publication
(10) Pub. No.: US 2026/0110732 A1
(43) Pub. Date: Apr. 23, 2026

(54) PROBE DEVICE AND TEST DEVICE INCLUDING THE SAME

(71) Applicant: Samsung Electronics Co., Ltd., Suwon-si (KR)

(72) Inventors: Seunghyeon Yun, Suwon-si (KR); Jindo Byun, Suwon-si (KR); Kyoungtae Kang, Suwon-si (KR); Youngdon Choi, Suwon-si (KR)

(21) Appl. No.: 19/329,038

(22) Filed: Sep. 15, 2025

(30) Foreign Application Priority Data
Oct. 23, 2024 (KR) 10-2024-0145567

(51) Int. Cl. G01R 31/317

(52) U.S. Cl. CPC G01R 31/31715

(57) ABSTRACT

An example probe device includes a plurality of command pins connected to a plurality of command/address pads included in a separate command/address (SCA) port of a first memory die, a plurality of data pins provided separately from the plurality of command pins, and a plurality of transmission lines connected to the plurality of data pins. Data pins of a first pin group among the plurality of data pins are connected to data pads of a first pad group among a plurality of data pads included in the first memory die. Data pins of a second pin group, different from the first pin group, are connected to data pads of a second pad group, different from the first pad group. The plurality of transmission lines electrically connect the data pins of the first pin group to the data pins of the second pin group.

### CROSS-REFERENCE TO RELATED APPLICATION

This application claims benefit of priority to Korean Patent Application No. 10-2024-0145567 filed on Oct. 23, 2024 in the Korean Intellectual Property Office, the disclosure of which is incorporated herein by reference in its entirety.

### BACKGROUND

A plurality of semiconductor dies may be manufactured from a wafer by various semiconductor processes performed on the wafer, and the plurality of semiconductor dies may be separated from each other by a scribing process. Prior to performing the scribing process, performance of at least one of the plurality of semiconductor dies may be tested at wafer level, and in the test operation at wafer level, a probe device including pins which may contact pads formed on the semiconductor die may be used. However, since the actual test operation is performed within the semiconductor die after a command signal for a test is input to the semiconductor die through the probe device, it may be difficult to measure characteristics of a signal which the semiconductor die transmits to an external entity or receives from an external entity through the pad.

### SUMMARY

The present disclosure relates to a probe device which may verify characteristics of a signal input from and output to data pads through a test at wafer level and a test device including the same by inputting a test command instructing a semiconductor die to perform a test into separate command/address (SCA) pads rather than data pads of the semiconductor die.

In general, according to some aspects, a probe device includes a plurality of command pins connected to a plurality of command/address pads included in a separate command/address (SCA) port of a first memory die; a plurality of data pins provided separately from the plurality of command pins; and a plurality of transmission lines connected to the plurality of data pins, wherein data pins of a first pin group among the plurality of data pins are connected to data pads of a first pad group among a plurality of data pads included in the first memory die, wherein data pins of a second pin group, different from the first pin group, are connected to data pads of a second pad group, different from the first pad group, and wherein the plurality of transmission lines electrically connect the data pins of the first pin group to the data pins of the second pin group.

In general, according to some aspects, a test device includes a probe device including a plurality of command pins, a plurality of data pins and a plurality of transfer paths electrically connecting data pins of a first pin group among the plurality of data pins to data pins of a second pin group different from the first pin group; and a control device configured to output a test command to the plurality of command pins for testing a memory die in contact with the plurality of command pins and the plurality of data pins, and configured to receive test result data from the memory die through the plurality of command pins, wherein the control device allows the plurality of data pins to be in contact with at least a portion of data pads through which the memory die transmits and receives a data signal, and allows the plurality of command pins to be in contact with command/address pads of the memory die different from the data pads.

In general, according to some aspects, a test device includes a probe device including a plurality of command pins, a plurality of data pins and a plurality of transfer paths electrically connecting at least a portion of the plurality of data pins to each other; and a control device configured to output a test command for testing a semiconductor die electrically connected to the probe device to the plurality of command pins and receive test result data, which is a result of a test operation executed by the semiconductor die in response to the test command, through the plurality of command pins, wherein the number of the plurality of command pins is less than the number of the plurality of data pins.

### BRIEF DESCRIPTION OF THE DRAWINGS

The above and other aspects, features, and advantages of the present disclosure will be more clearly understood from the following detailed description, taken in combination with the accompanying drawings.

FIGS. 1 and 2 are diagrams illustrating an example of a system including a semiconductor die.

FIG. 3 is a diagram illustrating an example of a process of manufacturing a semiconductor die.

FIGS. 4 and 5 are diagrams illustrating an example of a test method.

FIG. 6 is a diagram illustrating an example of a test device.

FIGS. 7 and 8 are diagrams illustrating operation of an example of a test device.

FIG. 9 is a diagram illustrating an example of a driver included in a semiconductor device, which is a test object of a test device.

FIGS. 10 and 11 are diagrams illustrating operation of an example of a test device.

FIG. 12 is a diagram illustrating test result data of an example of a test device.

FIG. 13 is a diagram illustrating operation of an example of a test device.

FIGS. 14 and 15 are diagrams illustrating operation of an example of a test device.

FIG. 16 is a diagram illustrating operation of an example of a test device.

FIG. 17 is a diagram illustrating operation of an example of a test device.

FIG. 18 is a diagram illustrating operation of an example of a test device.

### DETAILED DESCRIPTION

Hereinafter, implementations of the present disclosure will be described as follows with reference to the accompanying drawings.

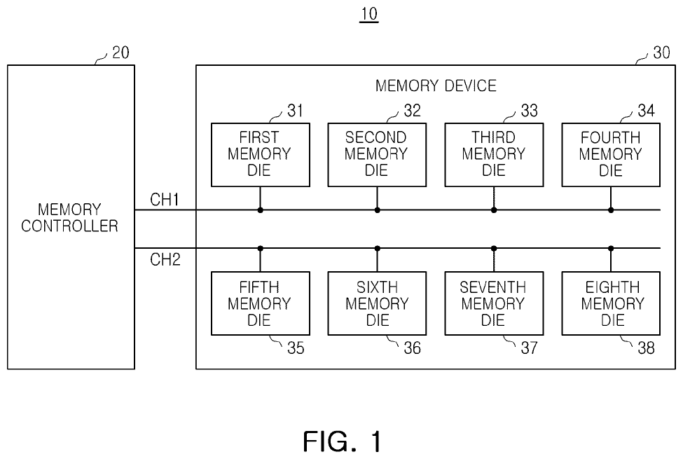

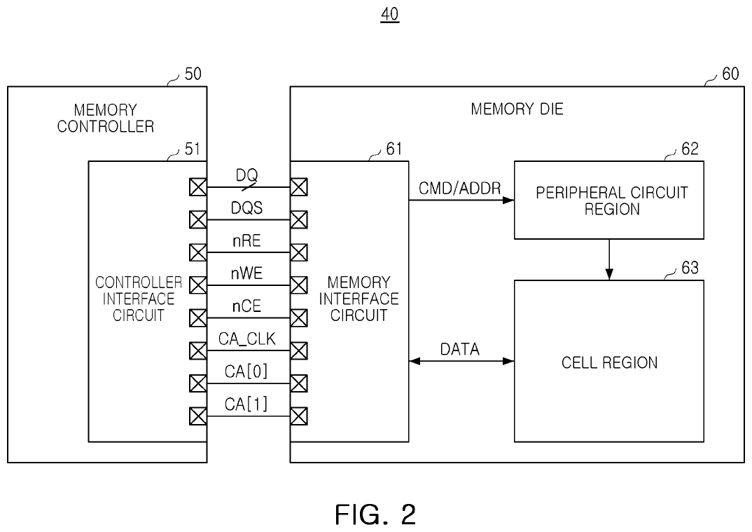

FIGS. 1 and 2 are diagrams illustrating an example of a system including a semiconductor die.

First, referring to FIG. 1, a system 10 may include a memory controller 20 and a memory device 30, and for example, the system 10 may be a storage system for storing data. The memory device 30 may include a plurality of semiconductor dies, and the plurality of semiconductor dies may be memory dies 31-38. A portion of the plurality of memory dies 31-38 may be connected to the memory controller 20 through a first channel CH1, and the other portion may be connected to the memory controller 20 through a second channel CH2.

In the example implementation illustrated in FIG. 1, the first to fourth memory dies 31-34 may be connected to the memory controller 20 through the first channel CH1, and the fifth to eighth memory dies 35-38 may be connected to the memory controller 20 through the second channel CH2. The first to fourth memory dies 31-34 may be included in one package, and the fifth to eighth memory dies 35-38 may be included in one package.

However, in some implementations, as for the plurality of memory dies 31-38, two memory dies may be included in one package, or eight memory dies 31-38 may be included in one package. The memory dies 31-38 included in one package may be connected to the memory controller 20 through a channel. Accordingly, when two memory dies of the plurality of memory dies 31-38 are included in each package, the memory controller 20 and the memory device 30 may be connected through four channels, and when eight memory dies 31-38 are included in one package, the memory controller 20 and the memory device 30 may be connected through a channel.

Characteristics of the signal transmitted through each of the channels CH1 and CH2 between the memory controller 20 and the memory device 30 may be determined according to the number of the memory dies 31-38 connected to each of channels CH1 and CH2. For example, in the example implementation in which four memory dies 31-38 are connected to each of the channels CH1 and CH2, characteristics of the signal transmitted to each of the channels CH1 and CH2 may be different from characteristics of the signal transmitted to each of the channels CH1 and CH2 in the example implementation in which two memory dies 31-38 are connected to each of the channels CH1 and CH2.

The test device may verify the characteristics of the signal transmitted to or received from an external entity by each of the memory dies 31-38 in an operation prior to performing a scribing process of separating the memory dies 31-38 from the wafer. The test device may include a probe device having pins electrically connected to the memory dies 31-38, and a portion of data pads included in each of the memory dies 31-38 may be electrically connected to each other by transfer paths within the probe device.

While a portion of data pads included in each of the memory dies 31-38 are electrically connected to each other by the probe device, each of the memory dies 31-38 may generate a test pattern. The test pattern may be output to one of the data pads and may be input to another data pad through a transfer path within the probe device. Each of the memory dies 31-38 may output test result data by comparing data received through the transfer path within the probe device with the test pattern to the test device, and the test device may verify the characteristics of the signal input from and output to the data pads.

Referring to FIG. 2, a system 40 may include a memory controller 50 and a memory die 60. FIG. 2 may be a diagram illustrating a connection structure of a memory controller 50 and a memory die 60. A controller interface circuit 51 of the memory controller 50 and a memory interface circuit 61 of the memory die 60 may be connected to each other.

A peripheral circuit region 62 of the memory die 60 may control a cell region 63 based on a command/address signal CMD/ADDR received from the memory interface circuit 61. The cell region 63 may store data DATA received from the memory interface circuit 61 or may output the stored data DATA to the memory interface circuit 61 in response to control of the peripheral circuit region 62.

The controller interface circuit 51 and the memory interface circuit 61 may exchange a chip enable signal nCE, a read enable signal nRE, a write enable signal nCE, a data strobe signal DQS, a data signal DQ, a command/address signal CA[1:0], and a command/address clock signal CA_CLK. In some implementations, the controller interface circuit 51 and the memory interface circuit 61 may exchange a data signal DQ with each other through a plurality of data signal lines. However, the signals transmitted between the controller interface circuit 51 and the memory interface circuit 61 are not limited to the signals as in the example.

As illustrated in FIG. 2, in some implementations, the memory interface circuit 61 may receive command/address data from the controller interface circuit 51 through a separate command/address signal CA[1:0] different from the data signal DQ. Accordingly, while the controller interface circuit 51 and the memory interface circuit 61 exchange the data signal DQ, the command/address data may be transmitted through command/address signal CA[1:0]. The command/address signal CA[1:0] may be transmitted in synchronization with the command/address clock signal CA_CLK, which is a separate clock signal from the data strobe signal DQS.

Accordingly, differently from a general method in which the test command is input to the memory die 60 through the data signal DQ, the test command may be input to the memory die 60 through the command/address signal CA[1:0]. The data pads inputting and outputting the data signal DQ in the memory die 60 may not be connected to a transfer path of the test command for performing the test operation. In some implementations, the test device may input the test command to the memory die 60 through the command/address signal CA[1:0], and the data pads of the memory die 60 may be connected to the transfer paths in the probe device.

For example, the memory die 60 may generate a test pattern in a pseudo-random manner in response to a test command. In some implementations, the test pattern generated by the memory die 60 may be output to a probe device through at least one data pad among the data pads, and may be input to another data pad through a transfer path in the probe device. The memory die 60 may verify characteristics of a signal input from and output to the data pad by comparing the data input through the transfer path in the probe device with the test pattern generated in response to the test command.

For example, the memory die 60 may generate test result data by measuring an eye margin of a signal input from and output to the data pad using a 2D-Shmoo technique, and may return the test result data to the test device. Accordingly, prior to performing the packaging of the memory die 60, characteristics of the signals transmitted and received by the memory die 60 may be verified using a test device, such that yield of the semiconductor manufacturing process may improve and reliability of the memory die 60 and the package including the same may improve.

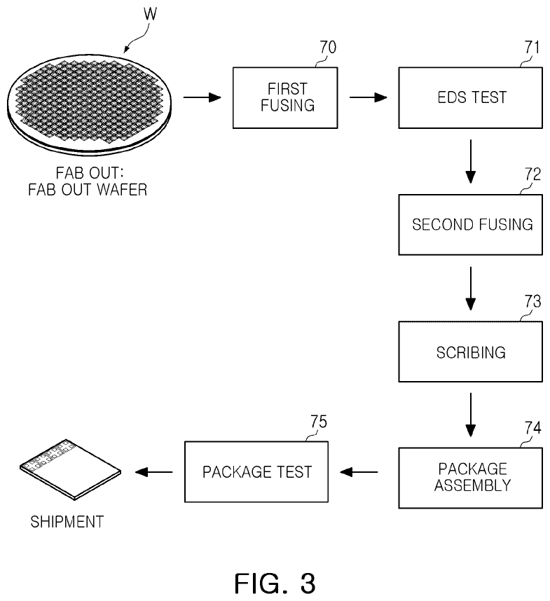

FIG. 3 is a diagram illustrating an example of a process of manufacturing a semiconductor die.

Referring to FIG. 3, a plurality of semiconductor devices may be manufactured by applying semiconductor processes to a wafer W, and the wafer W may be fab-out. The semiconductor devices may be disposed in the form of a semiconductor die on the wafer W. When the wafer W is fab-out, first fusing 70 of writing data to first fuse elements may be performed. The data written to the first fuse elements by the first fusing may include customizing data, repair data, and data related to a history of production/manufacturing the semiconductor device.

When the first fusing 70 is completed, an electrical die sorting (EDS) test 71 may be performed at wafer level. In some implementations, the EDS test 71 may include a plurality of tests performed in order in different environments. For example, the EDS test 71 may include a first EDS test and a second EDS test, and the first EDS test may be performed in a relatively high temperature environment, and the second EDS test may be performed in a relatively low temperature environment. When the EDS test 71 is completed, second fusing 72 of rewriting data of fuse elements may be performed. The second fusing 72 may be a procedure performed in consideration of possibility that data of fuse elements may be modified in the EDS test. When the second fusing 72 is completed, a scribing process 73 and a package assembly process 74 of separating semiconductor dies may be performed.

After the package assembly process 74, a package test 75 may be performed. For example, the package test 75 may be performed when a semiconductor device of which packaging is completed is mounted on a test board. The semiconductor device may exchange signals with other semiconductor devices through the test board, and accordingly, the package test 75 may test actual operation of the semiconductor device through the test board.

Generally, a test operation of verifying characteristics of signals which a semiconductor die exchanges with an external device may be performed in a package test 75. Accordingly, when it is determined in the package test 75 that the signals transmitted and received by the semiconductor die do not satisfy a given reference, the packaged semiconductor device may be discarded or the package assembly process 74 may need to be performed again.

In some implementations, the characteristics of signals input and output by the semiconductor die may be verified in the EDS test 71 performed at wafer level. Accordingly, yield of the semiconductor manufacturing process may be improved, and reliability of the semiconductor die and the semiconductor device manufactured by packaging the same may be improved.

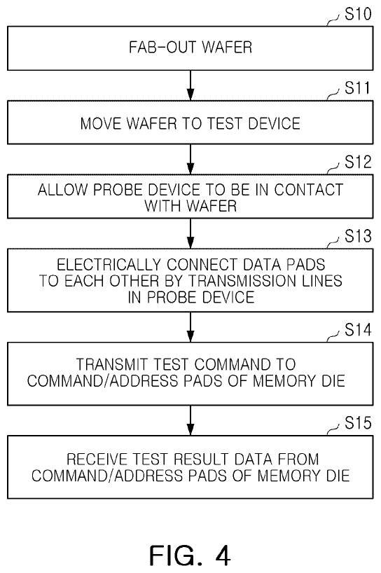

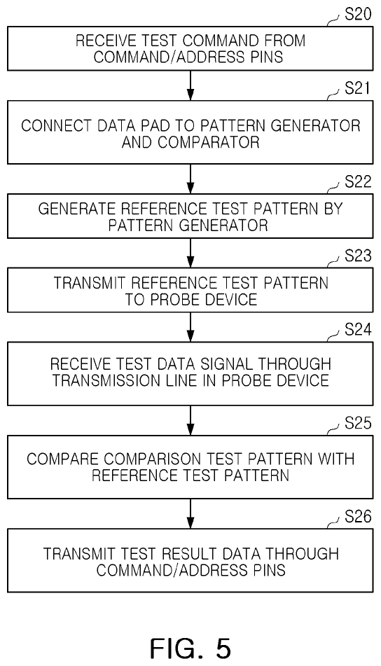

FIGS. 4 and 5 are diagrams illustrating an example of a test method.

Referring first to FIG. 4, a test method may start with manufacturing semiconductor dies by performing a semiconductor process on a wafer to and fab-outing the wafer (S10). The fab-out wafer may be in a state before performing a scribing process, and the semiconductor dies may be physically connected to each other. The fab-out wafer may move to a test device (S11).

The test device may be configured to perform a test on a semiconductor device formed on a wafer, and may be, for example, a device performing an EDS test. In some implementations, the test device may include a probe device including a plurality of pins, and a control device performing a test while exchanging signals with the semiconductor die by the probe device. In some implementations, the test device may perform tests on two or more semiconductor dies simultaneously while allowing the probe device to be in contact with two or more semiconductor dies.

When the wafer moves to the test device, the probe device may be in contact with the wafer (S12). The probe device may include a plurality of pins exposed to an external entity, and the plurality of pins may be in contact with pads formed on the semiconductor dies of the wafer, respectively. In some implementations, the plurality of pins included in the probe device may be connected to command/address pads and data pads included in the semiconductor die. The command/address pads may be pads providing SCA ports included in an interface of the semiconductor die.

Pins connected to the command/address pads may be defined as command pins, and pins connected to the data pads may be defined as data pins. The number of the command pins may be less than the number of the data pins, which may be because the number of the command/address pads included in the semiconductor die may be less than the number of the data pads.

The probe device may include a plurality of transmission lines connected to the data pins among the plurality of pins. For example, the plurality of transmission lines may be configured to electrically connect and separate a portion of the data pins from each other. When the probe device is in contact with the wafer, at least a portion of the data pins connected to the data pads of the semiconductor die may be electrically connected to each other by the transmission lines in the probe device. Accordingly, the data pads may be connected to each other (S13).

The test device may transmit a test command to the command/address pads of the memory die (S14). For example, the test device may supply a power voltage to the power pads of the memory die through the probe device, and may transmit a test command to the command/address pads through the command/address pins.

The test logic included in the memory die may be activated by the test command, and a built-in self-test (BIST) may be executed in the memory die. When the memory die completes the test operation and generates the test result data, the test device may receive the test result data from the memory die through the command/address pads instead of the data pads. (S15).

In some implementations, since the memory die receives the test command through the command/address pads instead of the data pads, various test operations may be performed using the data pads of the memory die. For example, by electrically connecting at least a portion of the data pads to each other through transmission lines in the probe device, characteristics of the driver and/or receiver connected to each of the data pads of the memory die may be verified while inputting and outputting signals to the data pads, which will be described in greater detail below with reference to FIG. 5.

Referring to FIG. 5, when a plurality of pins included in the probe device are in contact with a plurality of pads included in the memory die, the memory die may receive a test command from the command/address pins of the probe device (S20). As described above, among the pads of the memory die, the command/address pads may be connected to the command/address pins of the probe device, and among the pads of the memory die, the data pads may be connected to the data pins of the probe device.

The test logic of the memory die may be activated by the test command, and the test logic may connect the data pads to a pattern generator and a comparator (S21). For example, the first data pad among the data pads may be connected to the pattern generator, and the second data pad, which is different from the first data pad, may be connected to the comparator. The pattern generator may be connected to an input terminal of the driver connected to the first data pad, and the comparator may be connected to an output terminal of the receiver connected to the second data pad.

The pattern generator may generate a reference test pattern (S22). In some implementations, the reference test pattern may be generated in a pseudo random manner. The pattern generator may generate a reference test pattern based on an input value received from the test device along with a test command, or may generate a reference test pattern based on an initial value stored in a fusing operation performed prior to the test.

The reference test pattern generated by the pattern generator may be transmitted to the probe device (S23). For example, a test data signal including the reference test pattern may be transmitted to the probe device through the driver and the first data pad. As described above, the data pads of the memory die may be connected to the data pins of the probe device, and a portion of the data pads may be connected to each other by transmission lines in the probe device. The test data signal output to the first data pad may be transmitted to the transmission line in the probe device, and may be transferred back to the memory die through the second data pad. Accordingly, the memory die may receive a test data signal including a test pattern through a transmission line in the probe device (S24). For example, a receiver connected to the second data pad may receive the test data signal.

The receiver may generate a comparison test pattern from the test data signal. For example, the receiver may operate in synchronization with a predetermined clock signal, and may generate a comparison test pattern by comparing the test data signal with a reference voltage.

A comparator connected to an output terminal of the receiver may compare the comparison test pattern with a reference test pattern generated by a pattern generator in operation S22 (S25). Depending on characteristics of a driver, the transmission line in the probe device and the receiver, distortion may occur during a process of transmitting the test data signal. Accordingly, the reference test pattern and the comparison test pattern may not completely match each other. When the test result data including the comparison result of the reference test pattern and the comparison test pattern is generated, the memory die may transmit the test result data to the test device through the command/address pins (S26).

As described with reference to FIGS. 4 and 5, in some implementations, the test device may transmit the test command through the command/address pads instead of the data pads of the memory die. Accordingly, a portion of the data pads of the memory die may be connected to each other using transmission lines in the probe device, and the characteristics of the signals input and output by the driver and/or receiver connected to the data pads, such as an eye margin, may be verified. In some implementations, in the test operation, a load similar to an actual operating environment of the memory die may be determined on the data pads using the transmission lines in the probe device, and by performing the test of the memory die under a condition similar to the actual operating environment, defects in the memory die may be accurately detected and yield of the manufacturing process and reliability of the memory die may be improved.

In some implementations, by the transmission line in the probe device, data pads included in each of two or more different memory dies may be electrically connected to each other. For example, among the first data pad and the second data pad electrically connected to each other by a transmission line, the first data pad may be included in the first memory die, and the second data pad may be included in the second memory die. In some implementations, one data pad from each of the first to fourth memory dies may be selected and connected to the transmission line in the probe device. In this manner, operating environments depending on various package structures such as double die package (DDP), quarter die package (QDP), or octa die package (ODP) may be simulated, and test operations may be performed.

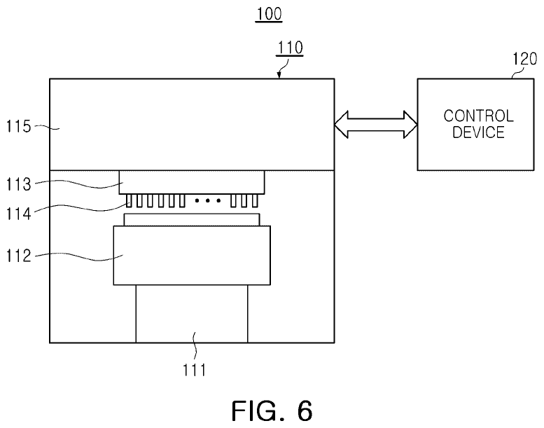

FIG. 6 is a diagram illustrating an example of a test device.

Referring to FIG. 6, a test device 100 may include a probe station 110 and a control device 120. The probe station 110 may include stages 111 and 112 on which a wafer W is mounted, a probe holder 113 on which probe devices 114 are mounted, and a probe head 115 transmitting a signal to or receiving a signal from the probe devices 114. The probe head 115 may be connected to and communicate with the control device 120.

When the wafer W is seated on the stages 111 and 112 by a wafer transfer device, a position of the wafer W may be adjusted by the stages 111 and 112 and may be aligned with the probe devices 114. For example, the first stage 111 may adjust a position of the wafer W in the horizontal direction, and the second stage 112 may adjust a position of the wafer W in the vertical direction.

Each of the probe devices 114 may include pins in contact with pads formed on semiconductor dies of the wafer W. When each of the semiconductor dies of the wafer W is a memory die, each of the probe devices 114 may include command/address pins connected to command/address pads of the memory die, data pins connected to data pads of the memory die, and power pins connected to power pads of the memory die.

Transmission lines may be disposed in each of the probe devices 114. The transmission lines may be connected to the data pins, and a portion of the data pads in contact with the data pins may be electrically connected to each other by the transmission lines. In some implementations, a single probe device 114 may be in contact with two or more semiconductor dies simultaneously, and in this case, data pads included in different semiconductor dies may be electrically connected to each other by transmission lines in the probe device 114.

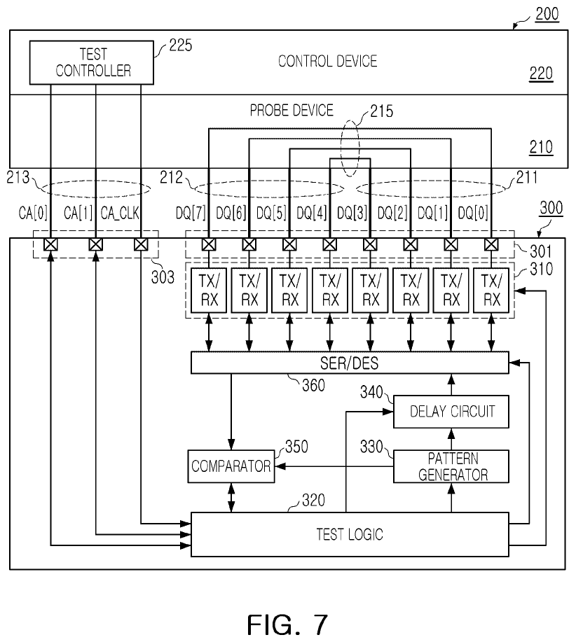

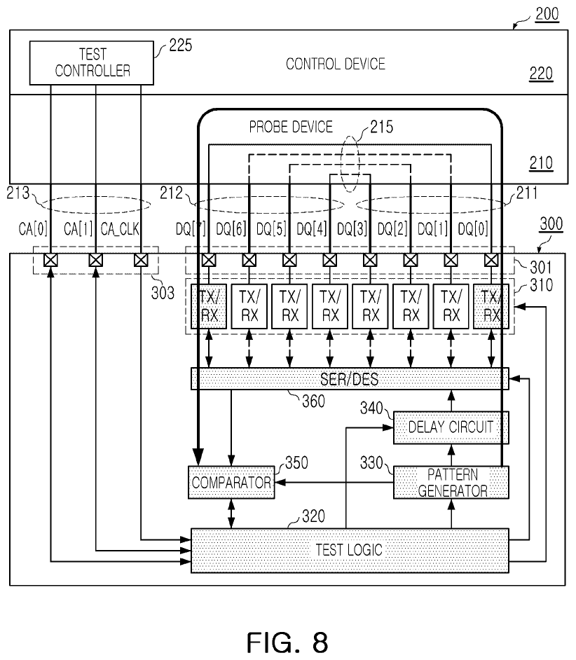

FIGS. 7 and 8 are diagrams illustrating operation of an example of a test device.

First, referring to FIG. 7, a test device 200 may include a probe device 210 and a control device 220. The probe device 210 may include a plurality of pins 211-213 and a plurality of transmission lines 215, and the control device 220 may include a test controller 225. The plurality of pins 211-213 may be connected to a plurality of pads 301-303 included in a memory die 300, which is a target to be tested.

As illustrated in FIG. 7, a plurality of pads 301-303 included in a memory die 300 may include data pads 301 inputting and outputting a data signal DQ[0:7], and command/address pads 303 inputting and outputting command/address data CA[0:1] and receiving command/address clock CA_CLK. To test the memory die 300, the data pads 301 may be in contact with data pins 211, 212 among the plurality of pins 211-213 included in the probe device 210, and the command/address pads 303 may be in contact with command/address pins 213 among the plurality of pins 211-213 included in the probe device 210.

The data pins 211 and 212 may be divided into the first pin group 211 and the second pin group 212. While the test of the memory die 300 is performed, the data pins of the first pin group 211 may be in contact with the data pads of the first pad group inputting and outputting the first to fourth data signal DQ[0:3]. While the test of the memory die 300 is performed, the data pins of the second pin group 212 may be in contact with the data pads of the second pad group inputting and outputting the fifth to eighth data signal DQ[4:7].

As illustrated in FIG. 7, the data pins of the first pin group 211 may be electrically connected to the data pins of the second pin group 212 by a plurality of transmission lines 215. Accordingly, in the example implementation illustrated in FIG. 7, the data pads of the first pad group and the data pads of the second pad group may match one to one and may be electrically connected to each other. For example, the first data pad inputting and outputting the first data signal DQ[0] may be electrically connected to the eighth data pad inputting and outputting the eighth data signal DQ[7], and the fourth data pad inputting and outputting the fourth data signal DQ[3] may be electrically connected to the fifth data pad inputting and outputting the fifth data signal DQ[4].

The method of connecting the data pads of the first pad group to the data pads of the second pad group may be varied depending on the configuration of the transmission lines 215. For example, the first data pad inputting and outputting the first data signal DQ[0] may be electrically connected to the fourth data pad inputting and outputting the fourth data signal DQ[3]. Also, one data pad may be electrically connected to two or more other data pads.

The memory die 300 may include transceivers 310, a test logic 320, a pattern generator 330, a delay circuit 340, a comparator 350, and a serializer 360 connected to data pads. In the example implementation illustrated in FIG. 7, only a portion of elements involved in a test operation among elements included in the memory die 300 are illustrated, and for example, the memory die 300 may further include a cell region in which memory cells are arranged in an array form, and a peripheral circuit region in which a row decoder, a page buffer, a voltage generator, and a control logic driving the cell region are disposed.

When the plurality of pins 211-213 included in the probe device 210 are in contact with the plurality of pads 301 and 303, the test controller 225 of the control device 220 may generate a test command. The test command may be transmitted to the test logic 320 through a plurality of command pins 213 and command/address pads 303. The test logic 320 may control the pattern generator 330 to generate a predetermined reference test pattern in response to the test command.

The reference test pattern may be input to the serializer 360 through the delay circuit 340, and the amount of delay to be reflected in the reference test pattern may be determined in the delay circuit 340. The serializer 360 may serialize the reference test pattern and may transfer the pattern to at least one of the transceivers 310. Each of the transceivers 310 may include a driver and a receiver, and the transceiver 310 receiving the serialized reference test pattern may output a test data signal including the reference test pattern through the driver. The test data signal may be output through the data pad 301 connected to the transceiver 310, may be transmitted through one of the transmission lines 215, and may be re-input to the memory die 300 through another data pad 301.

The receiver of another transceiver 310 connected to the other data pad 301 may generate a comparison test pattern using the test data signal. For example, the receiver may compare a predetermined reference voltage with the test data signal at a rising edge and/or falling edge of the clock signal and may recover the comparison test pattern from the test data signal. The comparison test pattern may be processed in parallel by the serializer 360 and may be input to the comparator 350.

The comparator 350 may compare the reference test pattern generated by the pattern generator 330 with the comparison test pattern recovered by the receiver. For example, the test data signal output by the driver and received by the receiver may reflect distortion due to influence of the driver, the receiver, and the transmission line 215. Due to the distortion as described above, the comparison test pattern generated by the receiver may not completely match the reference test pattern generated by the pattern generator 330.

The test logic 320 may generate test result data including a result of comparing a reference test pattern and a comparison test pattern. The test result data may be transmitted to the test controller 225 through the command/address pins 303 and the command pins 213, and the control device 220 may determine whether the memory die 300 is defective by referring to the test result data. Accordingly, in some implementations, characteristics of a driver transmitting a data signal DQ[0:7] to an external entity through the data pads 301 and/or a receiver receiving a data signal DQ[0:7] from an external entity through the data pads 301 may be verified by a test at wafer level, thereby improving reliability of the memory die 300 and yield of the manufacturing process.

FIG. 8 may be a diagram illustrating a test operation at wafer level. In the example implementation illustrated in FIG. 8, the test operation at wafer level may start with allowing a plurality of pins 211-213 to be in contact with a plurality of pads 301 and 303 and generating and outputting a test command by the test controller 225. The test command may be input to the test logic 320 through a plurality of command/address pins 213 and a plurality of command/address pads 303.

The test logic 320 receiving the test command may control the pattern generator 330 to generate a predetermined reference test pattern. The pattern generator 330 may generate the reference test pattern in a pseudo random manner, and may generate the reference test pattern based on an input value included in the test command or a reference value pre-stored in the memory die 300. The pattern generator 330 may delay the reference test pattern according to the amount of delay transferred by the delay circuit 340 and may transfer the pattern to the serializer 360.

In the test operation according to the example implementation illustrated in FIG. 8, the first transceiver connected to the first data pad inputting and outputting the first data signal DQ[0], and the eighth transceiver connected to the eighth data pad inputting and outputting the eighth data signal DQ[7] may be tested. When the serializer 360 transfers the test data signal serializing the reference test pattern to the first transceiver, the first driver included in the first transceiver may transmit the test data signal from the first data pad to an external entity.

The test data signal may be input to the eighth data pad through the transmission line 215 connecting the first data pad to the eighth data pad, and the eighth receiver of the eighth transceiver may receive the test data signal. The eighth receiver may recover the test data signal and transfers the signal to the serializer 360, and the serializer 360 may process the test data signal in parallel and may generate a comparison test pattern.

The comparator 350 may compare the comparison test pattern with the reference test pattern. The test logic 320 may transfer test result data including the comparison result of the comparison test pattern and the reference test pattern to the test controller 225 through the command/address pads 303 and the command/address pins 213. When the comparison test pattern recovered from the test data signal transmitted by the first driver and received by the eighth receiver matches the reference test pattern, the first driver and the eighth receiver of the memory die 300 may be recognized as having passed the test at wafer level. When the comparison test pattern does not match the reference test pattern, it may be determined that a defect is present in the first driver and the eighth receiver of the memory die 300.

In some implementations, the test logic 320 may compare a comparison test pattern with a reference test pattern while varying the amount of delay reflected by the delay circuit 340 to the test data signal and a level of a reference voltage input to an eighth receiver receiving the test data signal. Using the method described above, an eye margin of the test data signal may be measured using the 2D-Shmoo technique. The test logic 320 may transmit test result data including whether the comparison test pattern matches the reference test pattern and also the eye margin of the test data signal to the test device 200.

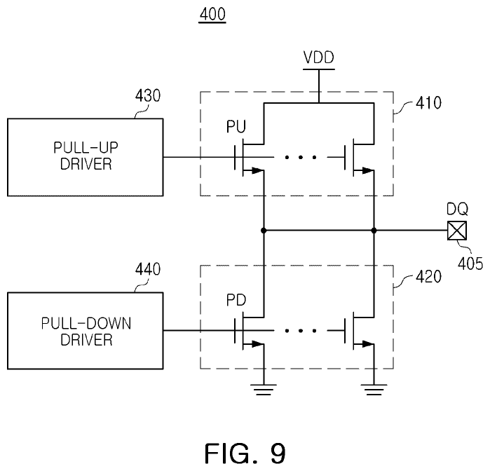

FIG. 9 is a diagram illustrating an example of a driver included in a semiconductor device, which is a test object of a test device.

Referring to FIG. 9, a driver 400 included in a semiconductor device may include a pull-up circuit 410, a pull-down circuit 420, a pull-up driver 430, and a pull-down driver 440. The driver 400 may be a circuit configured to output a data signal DQ through a pad 405.

The pull-up circuit 410 may include a plurality of pull-up elements PU connected in parallel between a power node supplying a power voltage VDD and the pad 405. The pull-down circuit 420 may include a plurality of pull-down elements PD connected in parallel between a reference node supplying a reference voltage, for example, a ground voltage, and the pad 405.

When the pull-up driver 430 turns on the pull-up elements PU, the pad 405 may be connected to the power node, thereby increasing a voltage level of the data signal DQ. When the pull-down driver 440 turns on the pull-down elements PD, the pad 405 may be connected to the reference node, and the voltage level of the data signal DQ may decrease.

Accordingly, the rising time and the falling time of the data signal DQ, and the swing range of the data signal DQ may be varied depending on the driver 400. For example, when an open defect is present in at least one of the pull-down elements PD, the falling time of the data signal DQ may increase. Also, as an example, when a short defect is present in at least one of the pull-down elements PD, the rising time of the data signal DQ may increase, or the voltage level of the data signal DQ corresponding to a high logic value may decrease. Due to the defects described above, the eye margin of the data signal DQ may decrease.

In some implementations, two or more pads included in a semiconductor device may be electrically connected to each other by a transmission line of a test device. Accordingly, a signal transmitted by a driver connected to one pad may be received by a receiver connected to another pad, and a test operation may be performed by comparing data recovered from the received signal with data encoded by the signal transmitted by the driver. By performing a test operation while changing the reference voltage input to the receiver receiving the signal and the amount of delay reflected in the signal transmitted by the driver, the eye margin of the signal may be verified, and whether the driver and receiver are defective may be determined.

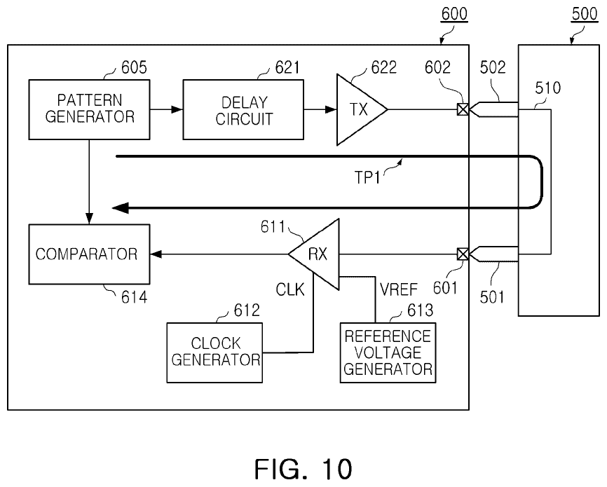

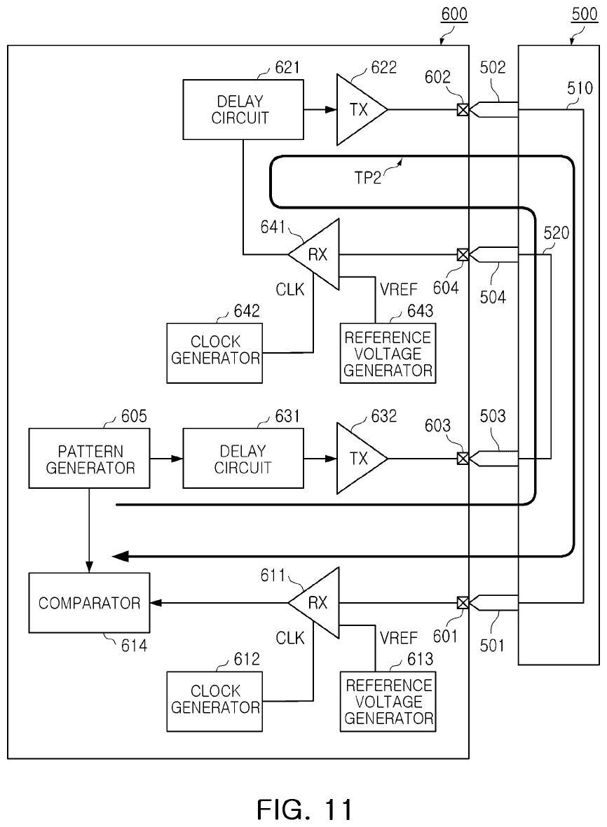

FIGS. 10 and 11 are diagrams illustrating operation of an example of a test device.

In the example implementation described with reference to FIGS. 10 and 11, the test device 500 may perform a test operation on the memory die 600. The test device 500 may include data pins 501-504 and transmission lines 510, 520. The data pins 501-504 may be connected to data pads 601-604 included in the memory die 600.

First, in the test operation according to the example implementation illustrated in FIG. 10, the first data pad 601 and the first data pin 501 may be in contact with each other, and the second data pad 602 and the second data pin 502 may be in contact with each other. A path for transmitting a signal may be formed between the first data pad 601 and the second data pad 602 by the first transmission line 510.

When the test operation starts, the pattern generator 605 of the memory die 600 may generate a predetermined reference test pattern and may transfer the pattern to the delay circuit 621. The delay circuit 621 may reflect a predetermined amount of delay in the reference test pattern and may transfer the pattern to the driver 622. In some implementations, a serializer may be connected between the delay circuit 621 and the driver 622, and the serializer may serially process the reference test pattern and may transfer the pattern to the driver 622.

The driver 622 may transmit a test data signal including the reference test pattern to the second data pad 602. For example, the driver 622 may transmit N bits of data included in the reference test pattern to the second data pad 602 at a rate of 1 bit per predetermined period. The test data signal may be input to the receiver 611 through the second data pin 502, the first transmission line 510, and the first data pin 501.

The receiver 611 may be synchronized to the clock signal CLK and may compare the test data signal with the reference voltage VREF. The sampling frequency of the receiver 611 may be determined depending on the frequency of the clock signal CLK. For example, the receiver 611 may compare the test data signal with the reference voltage VREF at least for each of the rising edge and falling edge of the clock signal CLK.

The output of the receiver 611 may be transferred to the comparator 614. For example, a parallelizer may be connected between the comparator 614 and the receiver 611, and the parallelizer may process an output of the receiver 611 in parallel and may transfer the output to the comparator 614. The comparator 614 may compare the comparison test pattern which the receiver 611 outputs by comparing the test data signal with the reference voltage VREF with the reference test pattern generated by the pattern generator 605. When the comparison test pattern and the reference test pattern match, it may be determined that the driver 622 and the receiver 611, which provide the first signal path TP1, may satisfy the target specification.

For example, while the test operation is performed, at least one of the amount of delay reflected by the delay circuit 621 to the driver 622, the phase of the clock signal CLK input to the receiver 611 by the clock generator 612, and the level of the reference voltage VREF generated by the reference voltage generator 613 may be adjusted. By adjusting at least one of the amount of delay reflected by the delay circuit 621 to the driver 622, and the phase of the clock signal CLK, the time point at which the receiver 611 compares the test data signal with the reference voltage VREF may be determined differently. Accordingly, the eye margin of the test data signal may be measured while adjusting the time point at which the test data signal is compared with the reference voltage VREF, and the level of the reference voltage VREF.

The test logic of the memory die 600 may transfer the eye margin of the test data signal to the test device 500 as test result data. Alternatively, only the result of comparing the eye margin measured from the test data signal with the reference range of the eye margin stored in advance may be transferred to the test device 500 as test result data. The test result data may be transmitted to the test device 500 through separate command/address pads, rather than the data pads 501 and 502, as described above.

The memory die 600 may be packaged in various structures, such as DDP, QDP, and ODP. Accordingly, by performing a test operation by simulating an operating environment similar to the actual structure in which the memory die 600 is packaged with the test device 500, the eye margin of the signal input and output by the memory die 600 may be verified accurately. In some implementations, the test operation may be performed by connecting the data pads 601-604 of the memory die 600 to each other in different manners using the transmission lines 510 and 520 included in the test device 500, and accordingly, an operating environment similar to an actual structure in which the memory die 600 is packaged may be simulated by the test device 500.

In the test operation according to the example implementation illustrated in FIG. 11, a second signal path TP2 connecting the four data pads 601-604 to each other may be generated. When the test operation starts, the pattern generator 605 may generate a reference test pattern. The reference test pattern may be converted into a test data signal by the driver 632 and may be output to the third data pad 603. For example, the phase of the test data signal may be adjusted by the delay circuit 631.

The test data signal may be input to the receiver 641 through the third data pin 503, the second transfer path 520, and the fourth data pin 504. The receiver 641 may compare the test data signal with the reference voltage VREF generated by the reference voltage generator 643 at the rising edge and/or falling edge of the clock signal CLK received from the clock generator 642. The output signal of the receiver 641 may be transferred to the driver 622 connected to the second data pad 602. For example, the phase of the output signal of the driver 622 may be adjusted by the delay circuit 621.

The signal output by the driver 622 to the second data pad 602 may be input to the first data pad 601 through the second data pin 502, the first transfer path 510, and the first data pin 501. The receiver 611 connected to the first data pad 601 may compare the reference voltage VREF generated by the reference voltage generator 613 with the signal received by the first data pad 601 at the rising edge and/or falling edge of the clock signal CLK received from the clock generator 612.

The output signal of the receiver 611 may be input to the comparator 614. For example, a parallelizer may be connected between the comparator 614 and the receiver 611, and the parallelizer may transfer a comparison test pattern which processes the output signal of the receiver 611 in parallel to the comparator 614. The comparator 614 may generate test result data by comparing the comparison test pattern, output by comparing the signal received by the receiver 611 by the first data pad 601 with the reference voltage VREF, with the reference test pattern generated by the pattern generator 605.

The second signal path TP2 according to the example implementation described with reference to FIG. 11 may be connected to two drivers 622 and 632 and two receivers 611 and 641, and may have a relatively larger load as compared to the first signal path TP1 according to the example implementation described with reference to FIG. 10. As described with reference to FIGS. 10 and 11, in some implementations, various signal paths TP1, TP2 having different load characteristics may be configured using data pads 601-604 included in one memory die 600, and a test operation may be performed based on the signal paths TP1, TP2.

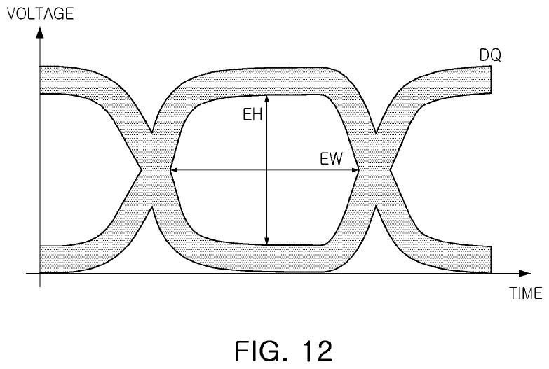

FIG. 12 is a diagram illustrating test result data of an example of a test device.

FIG. 12 may be a diagram illustrating the waveform of a test data signal TDQ transmitted in a signal path electrically connecting at least a portion of data pads included in a memory die to each other as described with reference to FIG. 10 and FIG. 11. For example, a signal path may be configured by electrically connecting at least a portion of data pads to transmission lines of a probe device.

The signal path may include a driver connected to a pattern generator, and a receiver connected to a comparator. The driver may convert a reference test pattern generated by the pattern generator into a test data signal TDQ and may outputs the signal, and the receiver may be synchronized to a predetermined clock signal, may compare the test data signal TDQ with a reference voltage and may generate a comparison test pattern. The comparator may compare the reference test pattern received from the pattern generator with the comparison test pattern received from the receiver.

The test data signal TDQ input to the receiver may have different waveforms for each cycle. For example, the phase and/or swing range of the test data signal TDQ input to the receiver may be varied depending on load characteristics of the signal path. Accordingly, as illustrated in FIG. 12, the eye width EW and the eye height EH, which determine the eye margin of the test data signal TDQ, may be determined depending on the load characteristics of the signal path.

In some implementations, a signal path connecting at least a portion of the data pads using transfer paths included in the probe device of the test device may be configured in various manners. Accordingly, a signal path may be configured with data pads in consideration of the load applied to each of the data pads of the packaged memory die, and the test data signal TDQ may be input from and output and may perform a test operation. By performing the test operation in a state in which the load applied to the data pads is similarly simulated depending on the package structure of the memory die, accuracy of the test operation may be improved, and characteristics of the driver and the receiver inputting and outputting the data signal may also be verified.

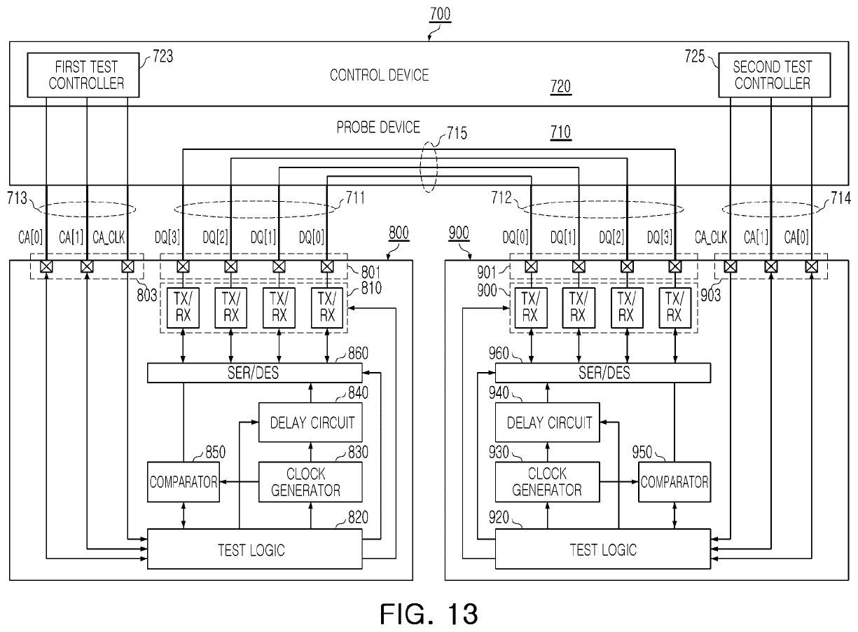

In some implementations, a probe device included in a test device may configure a signal path using two or more different memory dies. For example, a test operation may be executed in a state in which data pads included in a first memory die are electrically connected to data pads included in a second memory die by the probe device, which will be described in greater detail with reference to FIG. 13.

FIG. 13 is a diagram illustrating operation of an example of a test device.

Referring to FIG. 13, a test device 700 may include a probe device 710 and a control device 720. The probe device 710 may include a plurality of pins 711-714 and a plurality of transmission lines 715, and the control device 720 may include test controllers 723 and 725.

A portion of pins 711 and 713 of the plurality of pins 711-714 may be connected to a plurality of pads 801 and 803 included in a first memory die 800, and the other portion of pins 712 and 714 may be connected to a plurality of pads 901 and 903 included in a second memory die 900. A plurality of pins 711-714 may include a plurality of data pins 711 and 712 and a plurality of command pins 713 and 714.

Among the plurality of data pins 711 and 712, the data pins of the first pin group 711 may be connected to the data pads 801 of the first memory die 800, and the data pins of the second pin group 712 may be connected to the data pads 901 of the second memory die 900. Meanwhile, among the plurality of command pins 713, the first command pins 713 may be connected to the command/address pads 803 of the first memory die 800, and the second command pins 714 may be connected to the command/address pads 903 of the second memory die 900.

The data pins of the first pin group 711 and the data pins of the second pin group 712 may be electrically connected to each other by transmission lines 715 in the probe device 710. Accordingly, the data pads 801 of the first memory die 800 and the data pads 901 of the second memory die 900 may be electrically connected to each other. Referring to FIG. 13, the first data pads inputting and outputting the first data signal DQ[0] may be connected to each other, the second data pads inputting and outputting the second data signal DQ[1] may be connected to each other, the third data pads inputting and outputting the third data signal DQ[2] may be connected to each other, and the fourth data pads inputting and outputting the fourth data signal DQ[3] may be connected to each other.

The first memory die 800 and the second memory die 900 may be the same type of semiconductor devices which may perform the same function and may be manufactured on a single wafer. Before performing a scribing process of separating the first memory die 800 and the second memory die 900 from the wafer, as illustrated in FIG. 13, a test operation may be performed in a state in which the probe device 710 is in contact with the first memory die 800 and the second memory die 900 simultaneously.

The first memory die 800 may include transceivers 810, a test logic 820, a pattern generator 830, a delay circuit 840, a comparator 850, and a serializer 860 connected to data pads 801. The second memory die 900 may have the same structure as the first memory die 800. It may be understood that FIG. 13 illustrates only a portion of elements involved in the test operation among the elements included in each of the first memory die 800 and the second memory die 900. For example, each of the first memory die 800 and the second memory die 900 may further include a cell region in which memory cells are arranged in an array form, and a peripheral circuit region in which a row decoder, a page buffer, a voltage generator, and control logic for driving the cell region are disposed.

In the example implementation illustrated in FIG. 13, a test operation for each of the first memory die 800 and the second memory die 900 may be performed in a state in which a probe device 710 is in contact with the first memory die 800 and the second memory die 900. A signal path connecting at least one of the data pads 801 of the first memory die 800 and at least one of the data pads 901 of the second memory die 900 may be provided by the probe device 710, and the test operation may be performed while transmitting a signal to the signal path.

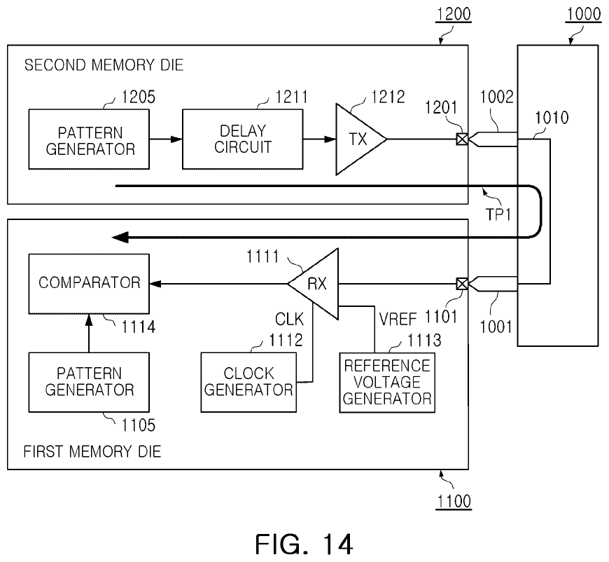

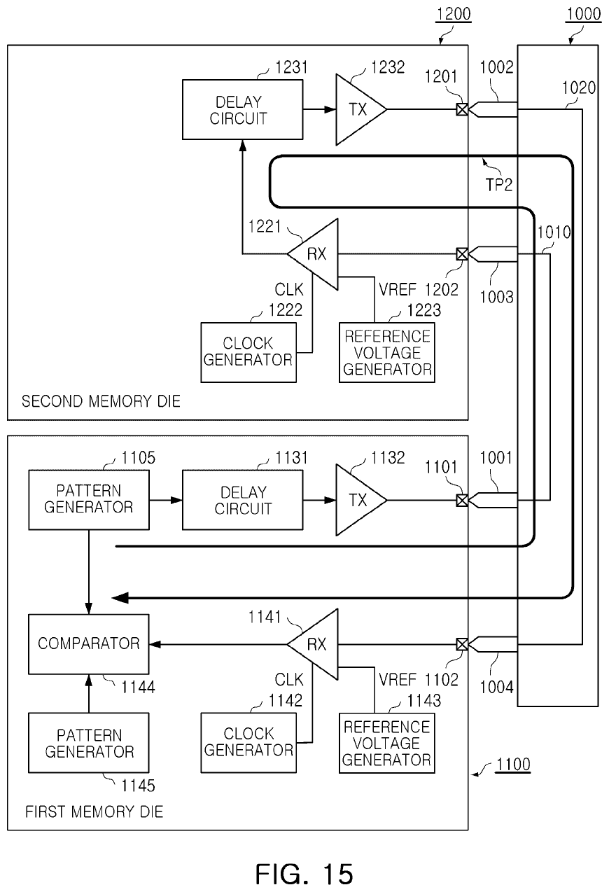

Test result data including a result of a test operation may be transmitted to the first test controller 723 and/or the second test controller 725. For example, when a final receiving end of a signal path provided by a probe device 710 is included in the first memory die 800, a test logic 820 of the first memory die 800 may transmit the test result data to the first test controller 723 through a command/address pads 803. When a final receiving end of a signal path provided by a probe device 710 is included in the second memory die 900, a test logic 920 of the second memory die 900 may transmit test result data to the second test controller 725 through a command/address pads 903. Hereinafter, a test operation using a plurality of memory dies 800 and 900 will be described in greater detail with reference to FIGS. 14 and 15.

FIGS. 14 and 15 are diagrams illustrating operation of an example of a test device.

In some implementations described with reference to FIGS. 14 and 15, a test device 1000 may perform a test operation on a first memory die 1100 and a second memory die 1200. The test device 1000 may include data pins 1001-1004 and transmission lines 1010 and 1020. A portion of the data pins 1001-1004 may be connected to data pads 1101 and 1102 included in the first memory die 1100, and the other pins of the data pins 1001-1004 may be connected to data pads 1201 and 1202 included in the second memory die 1200.

First, in the test operation according to the example implementation illustrated in FIG. 14, the first data pad 1101 and the first data pin 1001 of the first memory die 1100 may be in contact with each other, and the first data pad 1201 and the second data pin 1002 of the second memory die 1200 may be in contact with each other. A first signal path TP1 for transmitting a signal may be formed between the first data pad 1101 of the first memory die 1100 and the first data pad 1201 of the second memory die 1200 by the first transmission line 1010.

When the test operation starts, the pattern generator 1205 of the second memory die 1200 may generate a predetermined reference test pattern and may transfer the pattern to the delay circuit 1211. The delay circuit 1211 may reflect a predetermined amount of delay in the reference test pattern and may transfer the pattern to the driver 1212. In some implementations, the serializer may serialize the reference test pattern and may transfer the pattern to the driver 1212.

The driver 1212 may transmit a test data signal including the reference test pattern to the first data pad 1201. For example, the driver 1212 may transmit N bits of data included in the reference test pattern, one bit at a time at a predetermined period, to the first data pad 1201. The test data signal may be input to the receiver 1111 through the second data pin 1002, the first transmission line 1010, and the first data pin 1001.

The receiver 1111 may compare the test data signal with the reference voltage VREF at each of a rising edge and/or a falling edge of the clock signal CLK. The sampling frequency of the receiver 1111 may be determined according to the frequency of the clock signal CLK. The output of the receiver 1111 may be transferred to the comparator 1114. For example, a parallelizer may be connected between the comparator 1114 and the receiver 1111, and the parallelizer may process the output of the receiver 1111 in parallel and may transfer the output to the comparator 1114.

The comparator 1114 may compare the comparison test pattern, output by the receiver 1111 by comparing the test data signal with the reference voltage VREF, with the reference test pattern generated by the pattern generator 1105. The reference test pattern generated by the pattern generator 1105 of the first memory die 1100 may be the same as the reference test pattern generated by the pattern generator 1205 of the second memory die 1200.

For example, each of the pattern generators 1105 and 1205 may generate the reference test pattern in a pseudo-random manner based on an input value included in a test command received from the test device 1000 or a pre-stored reference value. By storing the same reference value in the first memory die 1100 and the second memory die 1200, or by transmitting a test command including the same input value to the first memory die 1100 and the second memory die 1200, the pattern generators 1105 and 1205 may generate the same reference test pattern. When the comparison test pattern and the reference test pattern match, it may be determined that the driver 622 and the receiver 611, which provide the first signal path TP1, may satisfy the target specification.

While the test operation is performed, at least one of the amount of delay reflected by the delay circuit 1211 to the driver 1212, the phase of the clock signal CLK input by the clock generator 1112 to the receiver 1111, and the level of the reference voltage VREF generated by the reference voltage generator 1113 may be adjusted. Accordingly, an eye margin of the test data signal may be measured by controlling the phase of the test data signal, the time point for comparing the test data signal with the reference voltage VREF, and the level of the reference voltage VREF.

The test logic of the first memory die 1100 may configure the eye margin of the test data signal as test result data and may transfer the data to the test device 1000. Alternatively, only the result of comparing the eye margin measured from the test data signal with the reference range of the eye margin stored in advance may be transferred to the test device 1000 as test result data. The test result data may be transmitted from the first memory die 1100 to the test device 1000 through separate command/address pads instead of the data pad 1101.

In the test operation according to the example implementation illustrated in FIG. 15, a second signal path TP2 connecting four data pads 1101, 1102, 1201, and 1202 to each other may be generated. When the test operation starts, the pattern generator 1105 of the first memory die 1100 may generate a reference test pattern. The reference test pattern may be converted into a test data signal by the driver 1122 and may be output to the first data pad 1101. For example, the phase of the test data signal may be adjusted by the delay circuit 1121.

The test data signal may be input to the receiver 1221 of the second memory die 1200 through the first data pin 1101, the first transfer path 1010, and the second data pin 1002. The receiver 1221 may compare the test data signal with the reference voltage VREF generated by the reference voltage generator 1223 at a rising edge and/or a falling edge of the clock signal CLK received from the clock generator 1222. The output signal of the receiver 1221 may be transferred to the driver 1232 connected to the second data pad 602 of the second memory die 1200. For example, the phase of the output signal of the driver 1232 may be adjusted by the delay circuit 1231.

The signal output by the driver 1232 to the second data pad 1202 may be input to the second data pad 1102 of the first memory die 1100 through the third data pin 1003, the second transfer path 1020, and the fourth data pin 1004. The receiver 1131 connected to the second data pad 1102 may compare the signal received to the second data pad 1102 with the reference voltage VREF generated by the reference voltage generator 1133 at the rising edge and/or the falling edge of the clock signal CLK received from the clock generator 1132.

The output signal of the receiver 1131 may be input to the comparator 1134. For example, a comparison test pattern obtained by processing the output signal of the receiver 1131 in parallel may be input to the comparator 1134 by the parallelizer connected between the comparator 1131 and the receiver 1134. The comparator 1134 may generate test result data by comparing the comparison test pattern with the reference test pattern generated by the pattern generator 1105. The test result data may be transmitted to the test device 1000 by the test logic included in the first memory die 1100. As described above, the test result data may include whether the comparison test pattern matches the reference test pattern, and the eye margin of the test data signal.

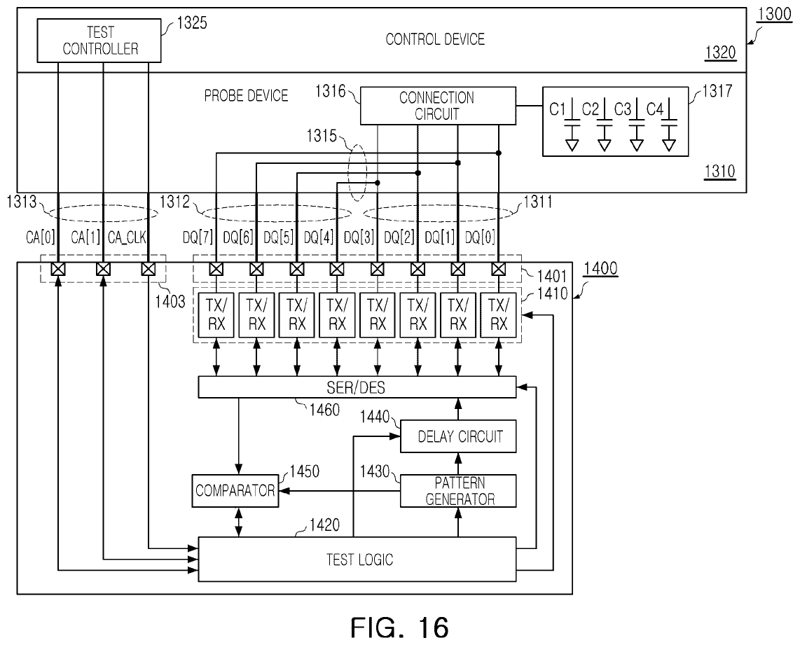

FIG. 16 is a diagram illustrating operation of an example of a test device.

In some implementations described with reference to FIG. 16, a test device 1300 may include a probe device 1310 and a control device 1320. The probe device 1310 may include a plurality of data pins 1311 and 1312 and a plurality of command pins 1313, and the plurality of data pins 1311 and 1312 may be greater than the plurality of command pins 1313. The plurality of data pins 1311 and 1312 may be in contact with data pads 1401 of a memory die 1400, and the plurality of command pins 1313 may be in contact with command/address pads 1403 of the memory die 1400. A data signal DQ[0:7] may be input and output through the data pads 1401, and command/address data CA[0:1] and command/address clock CA_CLK may be input and output through the command/address pads 1403.

The memory die 1400 may include transceivers 1410, a test logic 1420, a pattern generator 1430, a delay circuit 1440, a comparator 1450, and a serializer 1460 connected to data pads. In addition to the elements illustrated in FIG. 16, the memory die 1400 may further include a cell region in which memory cells are arranged in an array form, and a peripheral circuit region in which a row decoder, a page buffer, a voltage generator, and a control logic driving the cell region are disposed.

During a test of the memory die 1400, the data pins of the first pin group 1311 may be in contact with the data pads of the first pad group inputting and outputting the first to fourth data signal DQ[0:3], and the data pins of the second pin group 1312 may be in contact with the data pads of the second pad group inputting and outputting the fifth to eighth data signal DQ[4:7]. The data pins of the first pin group 1311 may be electrically connected to the data pins of the second pin group 1312 by a plurality of transmission lines 1315.

In the example implementation illustrated in FIG. 16, the probe device 1310 may further include a connection circuit 1316 and a plurality of capacitors 1317. The connection circuit 1316 may control connection between the plurality of transmission lines 1315 and the plurality of capacitors 1317. By connecting the plurality of capacitors 1317 to the plurality of transmission lines 1315 or separating the plurality of capacitors 1317 from the plurality of transmission lines 1315 using the connection circuit 1316, various load characteristics of the channel to which data pads 1401 are connected may be simulated.

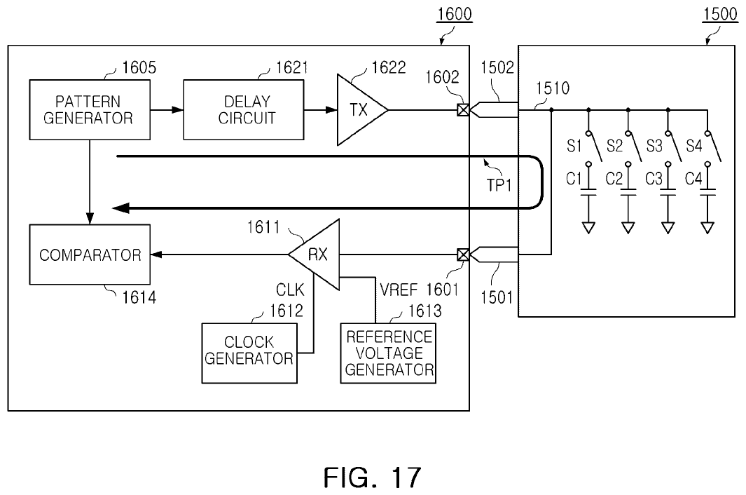

FIG. 17 is a diagram illustrating operation of an example of a test device.

In some implementations described with reference to FIG. 17, a test device 1500 may perform a test operation on a memory die 1600. The test device 1500 may include data pins 1501 and 1502, transmission lines 1510, a plurality of switches S1-S4 and a plurality of capacitors C1-C4. The transmission line 1510 and the plurality of capacitors C1-C4 may be connected to or separated from each other by the plurality of switches S1-S4.

To perform the test operation, a first data pin 1501 may be in contact with a first data pad 1601 of the memory die 1600, and a second data pin 1502 may be in contact with a second data pad 1602 of the memory die 1600. A signal path TP1 which may transfer a signal may be formed between the first data pad 1601 and the second data pad 1602 by the first transmission line 1510.

When the test operation starts, the pattern generator 1605 may generate a predetermined reference test pattern and may transfer the pattern to the driver 1622. The driver 1622 may output a test data signal including the reference test pattern to the second data pad 1602, and the phase of the test data signal may be adjusted by the delay circuit 162. The test data signal may be input to the receiver 1611 through the signal path TP1.

The receiver 1611 may be synchronized to the clock signal CLK and may compare the test data signal with the reference voltage VREF. For example, the receiver 1611 may compare the test data signal with the reference voltage VREF at the rising edge and/or the falling edge of the clock signal CLK. The output of receiver 1611 may be transferred to the comparator 1614, and for example, a comparison test pattern obtained by processing the output of receiver 1611 in parallel by parallelizer may be transferred to the comparator 1614.

The comparator 1614 may compare the comparison test pattern with the reference test pattern generated by the pattern generator 1605. When the comparison test pattern and the reference test pattern match, the driver 1622 and the receiver 1611, which provide the first signal path TP1, may be determined to satisfy the target specification. While the test operation is performed, the phase of the test data signal may be adjusted by the delay circuit 1621, and the sampling time point of the receiver 1611 may be adjusted according to the phase of the clock signal CLK. Also, the reference voltage VREF may be adjusted by the reference voltage generator 1613. In the above-described manner, the eye margin of the test data signal may be measured.

In the example implementation illustrated in FIG. 17, a plurality of capacitors C1-C4 may be connected to or separated from the signal path TP1 by controlling the turning on/off of a plurality of switches S1-S4. In some implementations, at least a portion of the plurality of capacitors C1-C4 may have different capacitances. Accordingly, test operations may be performed by simulating various conditions of channels to which data pads 1601 and 1602 may be connected after packaging the memory die 1600 with the signal path TP1.

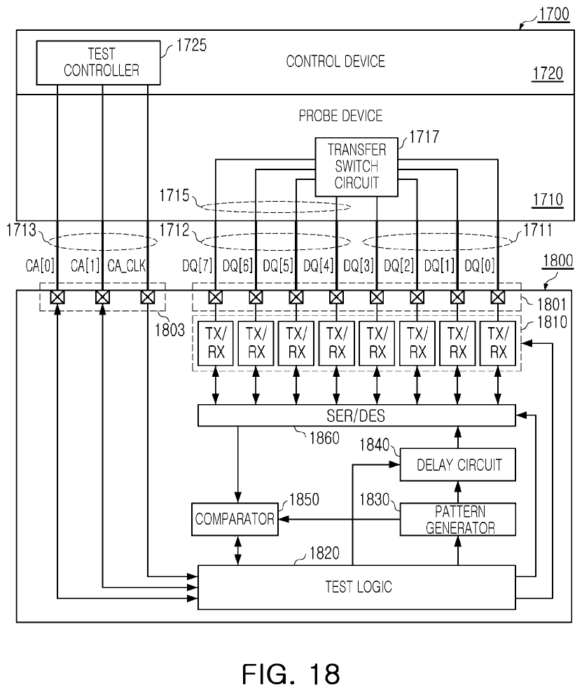

FIG. 18 is a diagram illustrating operation of an example of a test device.

In the example implementation described with reference to FIG. 18, the test device 1700 may include a probe device 1710 and a control device 1720. The probe device 1710 may include a plurality of data pins 1711 and 1712 and a plurality of command pins 1713, and the plurality of data pins 1711 and 1712 may be greater than the plurality of command pins 1713. The plurality of data pins 1711 and 1712 may be in contact with data pads 1801 of the memory die 1800, and the plurality of command pins 1713 may be in contact with command/address pads 1803 of the memory die 1800. A data signal DQ[0:7] may be input from and output to data pads 1801, and command/address data CA[0:1] and command/address clock CA_CLK may be input and output through the command/address pads 1803.

The memory die 1800 may include transceivers 1810, a test logic 1820, a pattern generator 1830, a delay circuit 1840, a comparator 1850, and a serializer 1860 connected to data pads. In addition to the elements illustrated in FIG. 16, the memory die 1800 may further include a cell region in which memory cells are arranged in an array form, and a peripheral circuit region in which a row decoder, a page buffer, a voltage generator, and a control logic driving the cell region are disposed.

While the memory die 1800 is tested, the data pins of the first pin group 1711 may be in contact with the data pads of the first pad group inputting and outputting the first to fourth data signal DQ[0:3], and the data pins of the second pin group 1712 may be in contact with the data pads of the second pad group inputting and outputting the fifth to eighth data signal DQ[4:7]. The data pins of the first pin group 1711 may be electrically connected to the data pins of the second pin group 1712 by a plurality of transmission lines 1715.

In the example implementation illustrated in FIG. 18, the probe device 1710 may further include a transfer switch circuit 1717. The transfer switch circuit 1717 may include a plurality of switches, and may select connection between a portion of transmission lines connected to the data pins of the first pin group 1711 and a portion of transmission lines connected to the data pins of the second pin group 1712. Accordingly, in the example implementation illustrated in FIG. 18, the connection between the data pads 1801 may not be fixed by the transmission lines 1715, and connection between the data pads 1801 may be varied by the transfer switch circuit 1717. The transfer switch circuit 1717 may be controlled by the control device 1720.

For example, in the example implementation illustrated in FIG. 18, the first data pad may be connected in sequence to the fifth to eighth data pads, and the test operation may be performed multiple times. Accordingly, the characteristics of the driver and receiver connected to each of the data pads 1801 may be verified under various conditions.

According to the aforementioned example implementations, prior to performing the scribing process of separating the plurality of semiconductor dies manufactured on a wafer, command pins of a probe device may be allowed to be in contact with command/address pads of the semiconductor die, data pins of the probe device may be allowed to be in contact with data pads of the semiconductor die, and a portion of the data pads may be connected to each other by transmission lines within the probe device. While the semiconductor die generates a test pattern and executes a test operation, the characteristics of signals input to and output from the data pads may be verified. Accordingly, by verifying the characteristics of signals transmitted to or received from an external entity by the semiconductor die during the test at wafer level, yield of the semiconductor process may be improved and reliability of the semiconductor device and package including the semiconductor die may be enhanced.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. A probe device comprising:
a plurality of command pins connectable to a plurality of command/address pads, the plurality of command/address pads being included in a separate command/address (SCA) port of a first memory die;
a plurality of data pins provided separately from the plurality of command pins; and
a plurality of transmission lines connected to the plurality of data pins,
wherein a first plurality of data pins of a first pin group among the plurality of data pins are connectable to a first plurality of data pads of a first pad group among a plurality of data pads, the plurality of data pads being included in the first memory die,
wherein a second plurality of data pins of a second pin group among the plurality of data pins are connectable to a second plurality of data pads of a second pad group among the plurality of data pads, the second pin group being different from the first pin group and the second pad group being different from the first pad group, and
wherein the plurality of transmission lines electrically connect the first plurality of data pins of the first pin group to the second plurality of data pins of the second pin group.

2. The probe device of claim 1, wherein the second plurality of data pads of the second pad group are a portion of the plurality of data pads included in the first memory die, and are different from the first plurality of data pads of the first pad group.

3. The probe device of claim 1, wherein the second plurality of data pads of the second pad group are a portion of a plurality of data pads included in a second memory die, the second memory die being different from the first memory die.

4. The probe device of claim 3, wherein a number of the portion of the plurality of data pads included in the second memory die is equal to a number of data pads in the first pad group.

5. The probe device of claim 1, comprising:
a plurality of capacitors; and
a connection circuit configured to control connection between the plurality of capacitors and the plurality of transmission lines.

6. The probe device of claim 1, wherein the plurality of transmission lines include a first plurality of transmission lines of a first line group connected to the first plurality of data pins of the first pin group, a second plurality of transmission lines of a second line group connected to the second plurality of data pins of the second pin group, and a plurality of transfer switches connected between the first plurality of transmission lines of the first line group and the second plurality of transmission lines of the second line group.

7. The probe device of claim 6, wherein a number of the first plurality of data pins of the first pin group is different from a number of the second plurality of data pins of the second pin group.

8. A test device comprising:
a probe device including a plurality of command pins, a plurality of data pins, and a plurality of transfer paths electrically connecting a first plurality of data pins of a first pin group among the plurality of data pins to a second plurality of data pins of a second pin group among the plurality of data pins, the second pin group being different from the first pin group; and
a control device configured to
output a test command to the plurality of command pins, the test command being configured to test a memory die contacting the plurality of command pins and the plurality of data pins, and
receive test result data from the memory die through the plurality of command pins,
wherein the control device is configured to allow the plurality of data pins to contact at least a first portion of a first plurality of data pads through which the memory die transmits and receives a data signal, and is configured to allow the plurality of command pins to contact a plurality of command/address pads of the memory die, the plurality of command/address pads being different from the first plurality of data pads.

9. The test device of claim 8,
wherein the memory die includes a test logic configured to execute a test operation based on the test command, a second plurality of data pads connected to the plurality of data pins, and a plurality of transceivers connected to the second plurality of data pads,
wherein each transceiver of the plurality of transceivers includes a driver and a receiver,
wherein the test logic is configured to measure an eye margin of a signal through which the second plurality of data pads transmits and receives based on changing at least one of delay of a test pattern input to the driver in the test operation, a reference voltage input to the receiver in the test operation, and a sampling time point of the receiver in the test operation, and
wherein the control device is configured to receive the test result data including the eye margin from the memory die.

10. The test device of claim 8, wherein the control device is configured to allow the first plurality of data pins of the first pin group to contact a second portion of the first plurality of data pads included in the memory die, and is configured to allow the second plurality of data pins of the second pin group to contact a third portion of the first plurality of data pads included in the memory die.

11. The test device of claim 8,
wherein the memory die is a first memory die, and
wherein the control device is configured to allow the first plurality of data pins of the first pin group to contact a second portion of the first plurality of data pads included in the first memory die, and is configured to allow the second plurality of data pins of the second pin group to contact a portion of a second plurality of data pads included in a second memory die, the second memory die being different from the first memory die.

12. The test device of claim 11, wherein a number of the second portion of the first plurality of data pads contacting the first plurality of data pins of the first pin group is equal to a number of the portion of the second plurality of data pads contacting the second plurality of data pins of the second pin group.

13. The test device of claim 8, wherein the control device is configured to output the test command to the plurality of command pins, the test command being configured to control a pattern generator included in the memory die to generate a predetermined reference test pattern.

14. The test device of claim 13, wherein based on the test command being output to the plurality of command pins, a test data signal corresponding to the reference test pattern is transmitted through a transfer path of the plurality of transfer paths.

15. The test device of claim 14,
wherein the transfer path electrically connects a first data pin and a second data pin to each other, and
wherein the control device is configured to allow the first data pin and the second data pin to contact a first data pad and a second data pad included in the memory die, respectively.

16. The test device of claim 14,
wherein the transfer path electrically connects a first data pin and a second data pin to each other, and
wherein the control device is configured to allow the first data pin to contact a first data pad included in a first memory die, and is configured to allow the second data pin to contact a second data pad included in a second memory die, the second memory die being different from the first memory die.

17. The test device of claim 13, wherein, based on the test command being output to the plurality of command pins, a test data signal corresponding to the reference test pattern is transmitted through two transfer paths among the plurality of transfer paths.

18. The test device of claim 17,
wherein a first transfer path among the two transfer paths electrically connects a first data pin and a second data pin to each other, and a second transfer path electrically connects a third data pin and a fourth data pin to each other, and
wherein the control device is configured to allow the first data pin, the second data pin, the third data pin, and the fourth data pin to contact the first data pad, the second data pad, the third data pad, and the fourth data pad included in the memory die, respectively.

19. The test device of claim 17,
wherein, among the two transfer paths, a first transfer path electrically connects a first data pin and a second data pin to each other, and a second transfer path electrically connects a third data pin and a fourth data pin to each other, and
wherein the control device is configured to allow the first data pin to contact a first data pad included in a first memory die, allow the second data pin to contact a second data pad included in a second memory die different from the first memory die, allow the third data pin to contact a third data pad included in the first memory die, and allow the fourth data pin to contact a fourth data pad included in the second memory die.

20. A test device comprising:
a probe device including a plurality of command pins, a plurality of data pins, and a plurality of transfer paths electrically connecting at least a portion of the plurality of data pins to each other; and
a control device configured to
output a test command to the plurality of command pins, the test command being configured to test a semiconductor die electrically connected to the probe device, and
receive test result data, which is a result of a test operation executed by the semiconductor die based on the test command, through the plurality of command pins,
wherein a number of the plurality of command pins is less than a number of the plurality of data pins.
